(19) United States
(12) Patent Application Publication
(10) Pub. No.: US 2009/0053507 A1
(43) Pub. Date: Feb. 26, 2009

(54) CONVERGENT-DIVERGENT-CONVERGENT NOZZLE FOCUSING OF AEROSOL PARTICLES FOR MICRON-SCALE DIRECT WRITING

(75) Inventors: Justin Michael Hoey, Fargo, ND (US); Iskander S. Akhatov, West Fargo, ND (US); Orven Fredrick Swenson, Fargo, ND (US); Douglas Lloyd Schulz, Moorhead, MN (US)

Correspondence Address: JOHN P. O'BANION;O'BANION & RITCHEY LLP, 400 CAPITOL MALL SUITE 1550, SACRAMENTO, CA, 95814, US

(73) Assignee: NDSU RESEARCH FOUNDATION, Fargo, ND (US)

(21) Appl. No.: 12/192,315

(22) Filed: Aug. 15, 2008

Related U.S. Application Data
(60) Provisional application No. 60/956,493, filed on Aug. 17, 2007.

(51) Int. Cl. B32B 5/16; B05B 7/00; C23C 16/44; B05D 5/12

(52) U.S. Cl. 428/323; 118/300; 427/255.25; 427/58; 427/124; 427/126.3

(57) ABSTRACT

A Convergent-Divergent-Convergent nozzle apparatus for direct-write applications is described. The tip apparatus includes at least three nozzles concentrically positioned in series. In a non-limiting embodiment, a first nozzle has a converging taper, a second nozzle extends from the first nozzle with a diverging taper, and a third nozzle extends from the second nozzle and has a converging taper. The nozzles are positioned in series and are coaxial, and can be formed from either separate components or a monolithic structure. Such an arrangement has permitted direct writing of aerosolized particle streams in line widths from 3.7-8 μm in width prior to sintering. Further refinements to the apparatus and processing parameters may result in line widths of 1 μm or less. Aerosolized particles may comprise conductor or semiconductor precursors that may be processed into microelectronic conductors or semiconductors, respectively. The particles may also comprise nanostructures or nanoparticles.

### CROSS-REFERENCE TO RELATED APPLICATIONS

This application claims benefit of priority to U.S. provisional patent application Ser. No. 60/956,493 filed on Aug. 17, 2007, which is hereby incorporated by reference in its entirety.

### STATEMENT REGARDING FEDERALLY SPONSORED RESEARCH OR DEVELOPMENT

This invention was made with Government support under Grant No. H94003-07-2-0701 awarded by the DMEA. The Government has certain rights in this invention.

### INCORPORATION-BY-REFERENCE OF MATERIAL SUBMITTED ON A COMPACT DISC

Not Applicable

### NOTICE OF MATERIAL SUBJECT TO COPYRIGHT PROTECTION

A portion of the material in this patent document is subject to copyright protection under the copyright laws of the United States and of other countries. The owner of the copyright rights has no objection to the facsimile reproduction by anyone of the patent document or the patent disclosure, as it appears in the United States Patent and Trademark Office publicly available file or records, but otherwise reserves all copyright rights whatsoever. The copyright owner does not hereby waive any of its rights to have this patent document maintained in secrecy, including without limitation its rights pursuant to 37 C.F.R. § 1.14.

### BACKGROUND OF THE INVENTION

1. Field of the Invention

This invention pertains generally to direct write fabrication methods and devices, more particularly to the focusing and collimation of aerosol particles emitted from deposition heads or tips used for direct write fabrication, and still more particularly to the focusing and collimation of aerosol particles emitted from deposition heads or tips used for direct write fabrication of line widths of 10 μm or less with little variance in run-to-run line height and width profiles.

2. Description of Related Art

As the Si-based Application Specific Integrated Circuit (ASIC) manufacturing community continues to develop new nanotechnology to address the challenges associated with Moore's Law and consequent device miniaturization, there is growing interest in developing low-cost methods of achieving large-area electronics. Such applications are well represented by recent industrial efforts toward roll-to-roll manufacture of solar cells (e.g., Nanosolar, Konarka, and Unisolar) and radio-frequency identification (RFID) tags (e.g., Alien, Kovio, and Avery Dennison). Such products may contain several components that require interconnection of the various circuit layers to allow appropriate overall function over a size dimension of several centimeters to several meters.

Direct write fabrication is a research area that has been active for years with special emphasis on technology development initiated through the DARPA Mesoscopic Integrated Conformal Electronics (MICE) program. The direct write process, de facto, is easily adapted to continuous manufacture approaches. One technology that resulted from the MICE program is Maskless Mesoscale Material Deposition (M³D). M³D utilizes a focused aerosol beam that allows the deposition of inorganic and organic materials onto polymer, glass, silicon, and alumina substrates in line widths down to 10 μm.

Nevertheless, there is still a need to improve the resolution of the known focused aerosol beam process to allow reproducible production of lines that maintain feature sizes of less than 10 μm width with little variation in run-to-run height and width. Such improvement is required if focused aerosol beam deposition is to be applied for fabricating impedance matched interconnects. Further, a precise deposition process control will allow minimization of expense associated with manufacture of electronic device components when precious metals (e.g. Ag and Au) are used as the interconnect materials. In addition, current focused aerosol beam approaches typically suffer from “overspray”, where lack of spray control results in discrete spots of the sprayed material (e.g. Ag or Au) outside the desired line width that may be deleterious for some high-frequency applications such as radio-frequency identification (RFID) tags. RFID products are generally manufactured via roll-to-roll processes in order to produce electronic materials over large areas. In such a manufacturing process, direct writing would appear to be a good candidate for additive materials deposition.

### BRIEF SUMMARY OF THE INVENTION

In one aspect of the invention, an aerosolized particle deposition apparatus comprises: (a) a final output port; and (b) means for spraying particles through the final output port. The final output port is the tip exit for the aerosolized particle deposition apparatus.

The means for spraying particles through the final output port may comprise: (a) a first nozzle having an input port, an output port, and a length, said first nozzle having a taper along its length, said output port of said first nozzle having a diameter smaller than its input port; (b) a second nozzle in series with said first nozzle, said second nozzle having an input port, an output port, and a length, said input port contiguous with said output port of said first nozzle, said second nozzle having a taper along its length, said output port of said second nozzle having a diameter larger than its input port; and (c) a third nozzle in series with said second nozzle, said third nozzle having an input port, the final output port, and a length, said input port contiguous with said output port of said second nozzle, said third nozzle having a taper along its length, the final output port of said third nozzle having a diameter smaller than its input port.

In another aspect of the invention, the diameter of the input port of the first nozzle may be approximately 800 μm. The diameter of the output port of the first nozzle may be approximately 50 μm to approximately 200 μm. The diameter of the input port of the second nozzle may be approximately 50 μm to approximately 200 μm. The diameter of the output port of the second nozzle may be approximately 800 μm. The diameter of the input port of the third nozzle may be approximately 800 μm. The diameter of the final output port of the third nozzle may be approximately 50 μm to approximately 200 μm.

Each of the nozzles above may have a length of approximately 9 mm to approximately 20 mm, however, the length is not limited to that range, and may be less than 9 mm, or greater than 20 mm.

In one aspect of the invention above: (a) the diameter of the input port of the first nozzle may be approximately 800 μm, (b) the diameter of the output port of the first nozzle may be approximately 150 μm, (c) the diameter of the input port of the second nozzle may be approximately 150 μm, (d) the diameter of the output port of the second nozzle may be approximately 800 μm, (e) the diameter of the input port of the third nozzle may be approximately 800 μm, and (f) the diameter of the final output port of the third nozzle may be approximately 100 μm.

In another aspect of the invention above: (a) the diameter of the input port of the first nozzle may be approximately 800 μm, (b) the diameter of the output port of the first nozzle may be approximately 150 μm, (c) the diameter of the input port of the second nozzle may be approximately 200 μm, (d) the diameter of the output port of the second nozzle may be approximately 800 μm, (e) the diameter of the input port of the third nozzle may be approximately 800 μm, and (f) the diameter of the final output port of the third nozzle may be approximately 100 μm.

Each of the three nozzles above may have a length of approximately 20 mm, however, the length is not limited to that range, and may be less than 9 mm, or greater than 20 mm. Additionally, each of the three nozzles may have a taper, where each respective taper may be selected from a group of tapers consisting of: substantially linear within about 1%, substantially linear within about 5%, substantially linear within 10%, substantially linear within 50%, and substantially linear within greater than 50%.

Here, linear is defined as a perfect line from an inner port diameter to an outer port diameter along a slicing plane coplanar with the axis of revolution of the nozzle. Such a perfect line may have a standard line equation of y=mx+b, where y is the radius, m is the slope of the line, and b is the slope offset. A percentage deviation from linearity means that the surface will at location x have a radius within δ percent of the radius y, i.e. a radius bounded by [1−δy, 1+δy].

Thus, in actuality, although each nozzle is loosely described as having a “taper”, with broad bounds of linearity of such taper, the nozzles could have second order or higher polynomials describing the curve of the nozzle between an input and an output port.

In the apparatus above, the two nozzles in series may extend from and be coaxial with the nozzle further from the final output. Few things manufactured are ever perfectly dimensioned, so by coaxial, one means substantially coaxial, with deviations of perhaps less than 1%, less than 3%, less than 10%, or even greater than or equal to 30% of the diameter of the smaller port.

In still another aspect of the invention, an aerosolized particle deposition apparatus may comprise: (a) a first nozzle having an input port, an output port, and a length, said first nozzle having a taper along its length, said output port of said first nozzle having a diameter smaller than its input port; (b) a second nozzle extending from and coaxial with said first nozzle, said second nozzle having an input port, an output port, and a length, said input port contiguous with said output port of said first nozzle, said second nozzle having a taper along its length, said output port of said second nozzle having a diameter larger than its input port; and (c) a third nozzle extending from and coaxial with said second nozzle, said third nozzle having an input port, an output port, and a length, said input port contiguous with said output port of said second nozzle, said third nozzle having a taper along its length, said output port of said third nozzle having a having a diameter smaller than its input port.

In the apparatus described above, the diameter of the input port of the first nozzle may be approximately 800 μm, the diameter of the output port of the first nozzle may be approximately 50 μm to approximately 200 μm, the diameter of the input port of the second nozzle may be approximately 50 μm to approximately 200 μm, the diameter of the output port of the second nozzle may be approximately 800 μm, the diameter of the input port of the third nozzle may be approximately 800 μm, the diameter of the output port of the third nozzle may be approximately 50 μm to approximately 200 μm, and each nozzle may have a length of approximately 9 mm to approximately 20 mm, however, the length is not limited to that range, and may be less than 9 mm, or greater than 20 mm.

In another aspect of the invention of the invention described above, the diameter of the input port of the first nozzle may be approximately 800 μm, the diameter of the output port of the first nozzle may be approximately 150 μm, the diameter of the input port of the second nozzle may be approximately 150 μm, the diameter of the output port of the second nozzle may be approximately 800 μm, the diameter of the input port of the third nozzle may be approximately 800 μm, and the diameter of the output port of the third nozzle may be approximately 100 μm.

In still another aspect of the invention of the invention described above, the diameter of the input port of the first nozzle may be approximately 800 μm, the diameter of the output port of the first nozzle may be approximately 150 μm, the diameter of the input port of the second nozzle may be approximately 200 μm, the diameter of the output port of the second nozzle may be approximately 800 μm, the diameter of the input port of the third nozzle may be approximately 800 μm, and the diameter of the output port of the third nozzle may be approximately 100 μm.

In the apparatus described above, each nozzle may have a length of approximately 20 mm, however, the length is not limited to that range, and may be less than 9 mm, or greater than 20 mm.

An aerosolized particle deposition apparatus may comprise the nozzles described above.

In another aspect of the invention, a method of aerosol particle deposition may comprise: (a) providing an aerosolized particle stream in a carrier gas; (b) providing a sheath gas; (c) flowing the aerosolized particle stream within the sheath gas to form a combined flow; and (d) flowing the combined flow through a series of convergent, then divergent, then convergent (CDC) nozzles.

The method above may comprise: (a) flowing the combined flow past a last output port in the CDC nozzle; and (b) impacting a substrate with the combined flow, (c) whereby aerosolized particles are deposited onto the substrate.

In the method above, the aerosolized particle stream may comprise nanoparticles with diameters selected from a group of diameters consisting of: less than 1 nm, less than 10 nm, less than 100 nm, less than 1 μm, and greater than or equal to 1 μm.

In another aspect of the invention, a product may be produced by the process described above.

In still another aspect of the invention, a conductive trace may be produced on a substrate by the process described above. Such conductive trace may be produced with a tip exit spaced above the substrate one or more distances selected from the group of distances consisting of: 1-5 mm, 1-4 mm, 2-3 mm, 2-2.5 mm, 1.75-2.00 mm, less than 1 mm, and greater than 5 mm.

The tip exit here is defined as the plane parallel to the final output port of a nozzle, which is generally perpendicular to the flow that passes though the nozzle.

Still other descriptions of the invention include a series tip having at least 3 nozzles, that comprises: (a) a first nozzle having an input port, an output port, and a length, said first nozzle having a taper along its length, said output port of said first nozzle having a diameter smaller than its input port (i.e., a converging taper); (b) a second nozzle in series with said first nozzle, said second nozzle having an input port, an output port, and a length, said input port contiguous with said output port of said first nozzle, said second nozzle having a taper along its length, said output port of said second nozzle having a diameter larger than its input port (i.e., a diverging taper); and (c) a third nozzle in series with said second nozzle, said third nozzle having an input port, an output port, and a length, said input port contiguous with said output port of said second nozzle, said third nozzle having a taper along its length, said output port of said third nozzle having a diameter smaller than its input port (i.e., a converging taper).

In one aspect of the invention, each nozzle is positioned in a series configuration where each downstream nozzle extends from and is coaxial with the adjacent upstream nozzle. By downstream, it is meant that a flow passes sequentially through the first, second, then third nozzles in the direction of the flow.

In another aspect of the invention, the diameter of the input port of the first nozzle is approximately 800 μm. In one aspect of the invention, the diameter of the output port of the first nozzle is approximately 50 μm to approximately 200 μm, and is possibly 50 μm to approximately 100 μm. In one aspect of the invention, the diameter of the input port of the second nozzle is approximately 100 μm to approximately 200 μm, and is possibly 50 μm to approximately 100 μm. In one aspect of the invention, the diameter of the output port of the second nozzle is approximately 800 μm. In one aspect of the invention, the diameter of the input port of the third nozzle is approximately 800 μm. In one aspect of the invention, the diameter of the output port of the third nozzle is approximately 50 μm to approximately 200 μm, and is possibly 100 μm to approximately 200 μm. In one aspect of the invention, the length of each nozzle ranges from approximately 9 mm to approximately 20 mm, however, the length is not limited to that range, and may be less than 9 mm, or greater than 20 mm.

In one aspect of the invention, the diameter of the input port of the first nozzle is approximately 800 μm, the diameter of the output port of the first nozzle is approximately 150 μm, the diameter of the input port of the second nozzle is approximately 150 μm, the diameter of the output port of the second nozzle is approximately 800 μm, the diameter of the input port of the third nozzle is approximately 800 μm, and the diameter of the output port of the third nozzle is approximately 100 μm.

In one aspect of the invention, the diameter of the input port of the first nozzle is approximately 800 μm, the diameter of the output port of the first nozzle is approximately 150 μm, the diameter of the input port of the second nozzle is approximately 200 μm, the diameter of the output port of the second nozzle is approximately 800 μm, the diameter of the input port of the third nozzle is approximately 800 μm, and the diameter of the output port of the third nozzle is approximately 100 μm.

In one aspect of a 3-nozzle series tip, by the time the aerosol particles reach the third nozzle they are focused to approximately 6% of the total diameter, and the third nozzle functions primarily to accelerate the particles. The 3-nozzle series tip may be comprised of a Convergent-Divergent-Convergent (CDC) nozzle configuration. The CDC nozzle may be capable of creating supersonic output flows. However, it may not be necessary to create a supersonic flow to focus or accelerate the particles.

In another aspect of the invention, the aerosolized particle stream may comprise precursor inks that contain precursor particles. These precursor particles, once further processed, transform into conducting or semiconducting structures that are suitable for use in electronic devices. The further processing is usually, but not exclusively, performed by heating, so as to sinter materials together, or to drive off volatile carriers or binders, resulting in the desired conducting or semiconducting electronic structure.

The precursor particles described above may comprise nanoparticles and/or nanostructures.

The particles suspended in the aerosolized particle stream may comprise conductor or semiconductor precursor inks that yield electronic-grade materials selected, without limitation, from a group of materials consisting of: Al, Au, Ag, Cu, Ni and C conductors; and Si, Ge, GaAs, GaInAs, AlGaAs, InP, ZnO, SnO₂, In₂O₃, CdO, Ga₂O₃ as semiconductors; and other materials that transform from a precursor to an electronic material. Generally, the transformation from the precursor to the electronic material is accomplished by time and temperature controlled heating.

The aerosolized particle stream may comprise: nanoparticles with diameters selected from a group of diameters consisting of: less than 1 nm, less than 10 nm, less than 100 nm, less than 1 μm, and greater than or equal to 1 μm.

The precursor inks may comprise semiconductor precursor inks that yield electronic-grade materials selected from a group of materials consisting of: Si, Ge, GaAs, GaInAs, AlGaAs, InP, ZnO, SnO₂, In₂O₃, CdO, Ga₂O₃ as semiconductors and other materials that transform from a precursor to an electronic material by subsequent processing. By “electronic-grade” it is meant that the resultant from suitably processing the precursor inks, a usable electronic device is obtained.

A product may be produced by the processes described above. A conductive trace may be produced on a substrate by the process described above. A semiconductor device may also be produced on a substrate by the process described above. When either a conductor or semiconductor is produced, it is necessary that a suitable precursor ink be used so that the desired conductor or semiconductor is produced, usually through subsequent processing steps such as heating.

While a 3-nozzle series tip represents one aspect of the invention, any configuration using at least 3 series nozzles is also within the scope of the present invention. That is, they do not need to form a CDC nozzle set.

In other aspects of the invention, the sheath fluid above may be substantially chemically inert relative to the aerosolized particles, as may be the carrier. The carrier fluid and sheath fluid may comprise substantially nitrogen N₂. The carrier fluid and sheath fluid may comprise substantially air that is substantially dry, so as to prevent ice formation from the fluid or sheath flows.

Further aspects of the invention will be brought out in the following portions of the specification, wherein the detailed description is for the purpose of fully disclosing embodiments of the invention without placing limitations thereon.

### BRIEF DESCRIPTION OF THE SEVERAL VIEWS OF THE DRAWINGS

The invention will be more fully understood by reference to the following drawings which are for illustrative purposes only:

FIG. 1 is a graph of beam widths versus distance from the 100 μm tip exit of: (a) experimental results with 0.6 μm particle diameter, 40 Standard Cubic Centimeters per Minute (SCCM) total flow rate, 1600 kg/m³ particle density; (b) a theoretical model using drag forces only (Theoretical: Stokes Only); and (c) a theoretical model using drag and lift forces (Theoretical, Stokes + Saffman).

FIG. 2 is a cross sectional view of test setup for testing the particle beam flow of aerosol particles leaving a 100 μm tip exit, at 40 SCCM total flow, and 1600 kg/m³ particle density. Focusing of the particle beam is observed.

FIG. 3 is a graph of theoretical beamwidths versus distance from 100 μm tip exit for particle diameters of 0.2 μm, 0.6 μm, and 1 μm.

FIG. 4 is a cross-section view of a Convergent-Divergent-Convergent (CDC) nozzle comprising three coaxially juxtaposed nozzles, showing the nozzle profiles and trajectories of the aerosol particles comprising the particle beam.

FIG. 5 is a graph of beam widths versus distances from the tip exit for the CDC nozzle with 150 μm and 100 μm nozzle throats, and the 100 μm M³D nozzle, plotted with experimental results, as well as theoretical results with Saffman and Stokes forces, and with just the Stokes force modeled. It should be noted that the 100 μm M³D nozzle curves were previously presented in FIG. 2, and are incorporated here for comparison purposes only.

FIG. 6 is a perspective view of an experimental substrate with a 1 mm vertical surface step, prepared for direct write fabrication of lines deposited on the substrate with a test nozzle in place.

FIG. 7 is a photomicrograph showing the lines written by the 100 μm M³D nozzle of FIG. 2 and the CDC nozzle of FIG. 4, as both nozzles pass over the substrate with the 1 mm surface step of FIG. 6.

FIG. 8 is a photomicrograph of an 8.7 μm wide line written by the CDC nozzle with 25 SCCM carrier gas, 15 SCCM of sheath gas, with a stage translation velocity of 30 mm/s (left frame), and the same nozzle with 20 SCCM of carrier gas, 25 SCCM of sheath gas, and a roughly 25 μm wide line written with 5 mm/s stage translational velocity (right frame).

FIG. 9 is an angled overhead Scanning Electron Micrograph (SEM) view of a line written by the CDC nozzle of FIG. 4 on glass with 10 SCCM carrier gas, a total of 20 SCCM sheath gas (10 SCCM was introduced first into the carrier gas stream), and a stage translation speed of 5 mm/s. The line width is about 11 μm (on left panel), and a cross section of the same line (on right panel) shows line heights of 1.15, 1.28, 1.65, and 1.54 μm respectively, measured left to right.

FIG. 10 is an overhead photomicrographic view of lines from FIG. 9 that were written onto double sided tape, with three magnifications increasing from the left to right views. The flow rates used here were 20 SCCM for the sheath gas, and 10 SCCM for the carrier gas. Line widths appear here to be approximately 3.7 μm.

FIG. 11 is a SEM image of a line printed in a fashion similar to that of FIG. 10 with a line width of approximately 5.3 μm, where significant overspray was observed.

FIG. 12 is a SEM image of cross sections of one of the lines of FIG. 10 written on double-sided tape, with an approximate width of 6.2 μm, where it appears that the line has formed a trench within the substrate through a particle-substrate interaction.

### DETAILED DESCRIPTION OF THE INVENTION

### Definitions

The following terms are used herein and are thus defined to assist in understanding the description of the invention(s). Those having skill in the art will understand that these terms are not immutably defined and that that the terms should be interpreted using not only the following definitions but variations thereof as appropriate in the context of the invention(s).

Aerosol means a suspension of particles in a carrier fluid.

Carrier fluid means a generally nonreactive fluid suitable for suspending a flow of particles in an aerosol particle stream.

A convergent nozzle narrows down from a wider diameter to a smaller diameter in the direction of the flow. Convergent nozzles accelerate subsonic fluids. If the nozzle pressure ratio is sufficiently high the flow will reach sonic velocity at the narrowest point (i.e. the nozzle throat).

A divergent nozzle expands from a smaller diameter to a larger diameter in the direction of the flow. Divergent nozzles slow fluids if the flow is subsonic, but accelerate sonic or supersonic fluids.

Fluid means a substance that continually deforms (flows) under an applied shear stress regardless of how small the applied stress. All liquids and all gases are fluids. Fluids are a subset of the phases of matter and include liquids, gases, and plasmas. The term “fluid” is often erroneously used as being synonymous with “liquid”.

Nanoparticles mean small objects that behave as individual units in terms of its transport and properties, and are sized between 1 and 100 nanometers, though the size limitation can be restricted to two dimensions (as in nanowires), or one dimension (as in nanocarpets).

Nanostructure means elements comprising: a single or multiwalled nanotube, nanowire, nanoropes comprising a plurality of nanowires, nanocrystals, nanohorns, nanocarpets; and constructs comprised of the foregoing elements and/or other nanoparticles.

Nozzle means a physical device or orifice designed to control the characteristics of a fluid flow as it exits (or enters) an enclosed chamber or pipe. A nozzle is often a pipe or tube of varying cross sectional area that can be used to direct or modify the flow of a fluid. Nozzles are frequently used to control the rate of flow, speed, direction, mass, shape, and/or the pressure of the stream that emerges from them.

Sheath fluid means a generally nonreactive fluid generally surrounding the flow of aerosolized particles in a particle stream.

Spraying means a projecting a stream of particles in a carrier fluid as an aerosolized particle stream, which may be substantially collimated over a distance. The particles may be nanostructures or other atomic or molecular components, and may be comprised of a mixture comprising any of the foregoing. The carrier fluid carries the particles to be sprayed, which may be enclosed by a sheath fluid and focused into a substantially collimated particle stream (at least for a certain distance) with the help of the sheath fluid.

Throat means the narrowest part of a nozzle.

### Introduction

It is known that when an aerosol expands through a converging nozzle, the particles may focus at a distance downstream from the nozzle. Focusing of aerosol results from inertial effects, where particles are accelerated through a converging nozzle, thus obtaining a radially convergent inward motion. This inward motion is somewhat retained downstream of the nozzle, even as the rapidly expanding propellant (or carrier) fluid diverges radially outward. This classic concept of aerodynamic focusing of aerosol beams is based on particle inertia and the Stokes force (which is drag of a particle in a fluid such as air or nitrogen gas) of interaction between particles and fluid flow. It is a correct approximation for the aerosol flow through the nozzle. However, for different geometries of the flow, the hydrodynamic fluid-particle interaction in the aerosol beam cannot be described by the Stokes force only.

In contrast, here, an invention is designed based upon utilizing the Saffman force acting on aerosol particles in gas flowing through a micro-capillary, which under proper conditions may cause migration of particles towards the center axis of the capillary. This approach is novel in contrast to the classical aerodynamic focusing method where only particle inertia and the Stokes force of gas-particle interaction are employed.

Near perfect collimation can theoretically be achieved with a long capillary of constant diameter. Such a long capillary could be used for collimating the aerosol particles; however, clogging of the long capillary would most likely result. To reduce nozzle clogging, the length of the portion of nozzle tip geometry at the smallest diameter needs to be reduced.

An arrangement of three nozzles in series allows for the length of the tip at its smallest diameter to be minimized. The particles flowing through such a set of nozzles will then become much more collimated, and in certain theoretical cases completely collimated.

### EXAMPLE 1

A thorough characterization of aerodynamic focusing was completed on a CoorsTek (formerly Gaiser Tool Inc., 4544 McGrath St. Ventura, Calif. 93003) aluminum oxide micro-capillary, 100 μm final diameter, part number 1551-40-750P-200 (1.5-F-20), under a flow rate of 30 SCCM carrier fluid, and 10 SCCM sheath fluid. Both the sheath and carrier gases were dry nitrogen. The beam width was determined at 0.25 mm intervals from the tip exit. A total of nine repetitions were carried out on different days to determine the deviation of beam width due to time variability. Data was taken via a Sony ExWave HAD CCD camera that is able to record 640×480 pixel pictures. The pictures were then transferred to MATLAB software where they were normalized. Beam width was measured using a minimum intensity at half max. Beam widths at ten different locations on the picture were determined, and the average of these ten locations was taken as the beam width.

The beam width vs. distance measurements were used as a comparison with the theoretical model. From the comparison, the physics of aerodynamic focusing was determined.

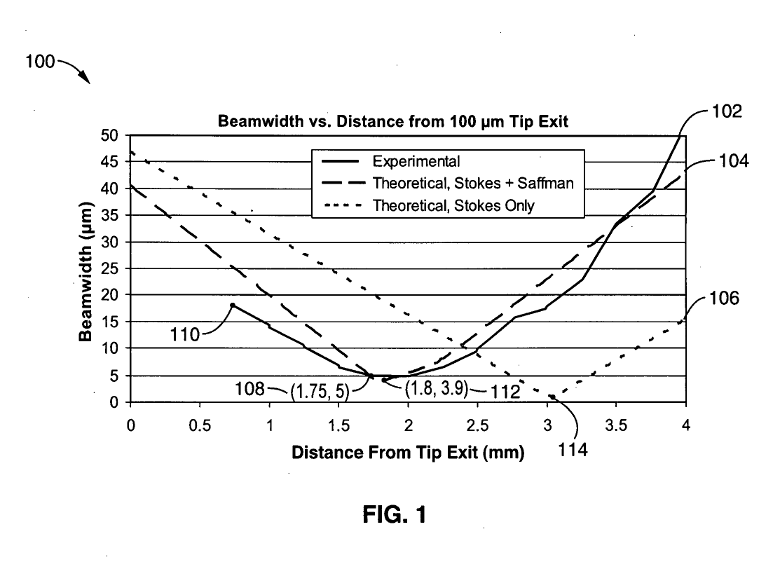

Refer now to FIG. 1, which is a graph 100 of the beam width produced experimentally and theoretically as a function of distance in this Example 1. Here, the tip is 100 μm in diameter, with a 40 SCCM total flow rate. By using the graphed experimental data 102 it may be inferred that the particle diameter is 0.6 μm with a 1600 kg/m³ particle density. The experimental width uses half max data, and the theoretical width is determined with: 1) Saffman (fluid induced lift) and Stokes (fluid induced drag) forces applied 104; and 2) only Stokes (fluid induced drag) force applied 106.

It can be seen from the experimental data 102 that a focal distance appears at approximately 1.75 mm from the tip exit with a beam width of about 5 μm 108. Measured data closer than 0.75 mm from the tip exit could not be analyzed due to light reflections from the tip 110. The theoretical model fit best for both cases when the particle size was 0.6 μm, and the density of the particles was 1600 kg/m³.

A theoretical model using both the Saffman and Stokes forces 104 most closely resembled the experimental data 102 with an r² value of 0.93, where the apparent trend of focusing is very similar. Maximum focusing occurs at about 1.8 mm past the tip with a beam width of 3.9 μm 112.

The theoretical model using only Stokes force 106 does not correlate well to the experimental data 102 with an r² value of 0.05. In the Stokes force model 106, the beam focus is at 3 mm past the tip with a beam width of 0.9 μm 114. The focal distance of the aerosol beam is increased without considering the Saffman force because forces acting tangential to the axis of the tip on the aerosol particles are reduced without Saffman force. With Stokes forces only, focusing occurs due to the geometry of the tip, which in this case would allow for the focal point to be no closer than 2.8 mm from the end of the tip. The focal distance could be greater, depending on the lag of the aerosol particles following the streamlines.

Saffman forces are indeed acting on the aerosol particles in this flow situation to obtain the current focusing, as may be concluded by the comparisons of: 1) the measured data 102, 2) the plot of the Saffman (fluid induced lift) and Stokes (fluid induced drag) forces applied 104; and 3) the plot of only the Stokes (fluid induced drag) force applied 106.

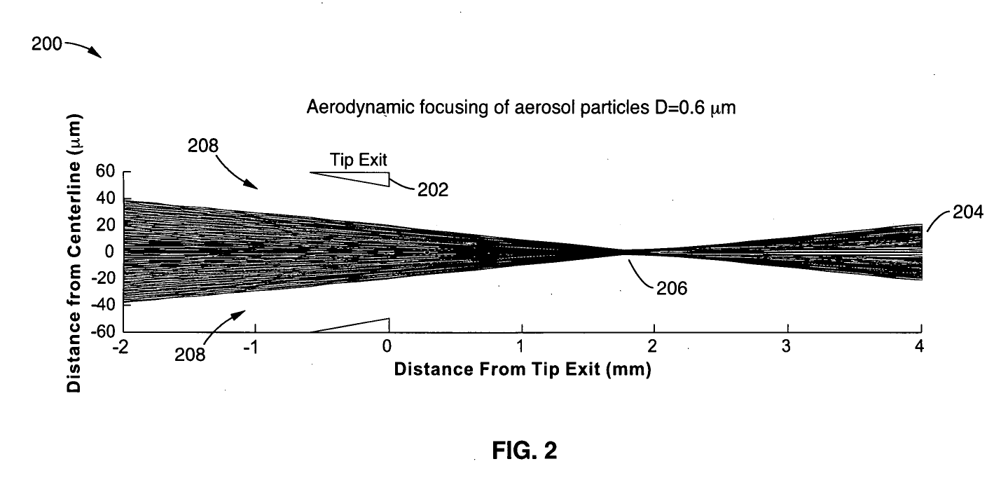

Refer now to FIG. 2, which is a cross section 200 of the theoretical trajectories of the aerosol particles across the axis of rotation based on the inclusion of both the Saffman and Stokes forces. Here, the convergent nozzle tip 202 produces aerodynamic focusing of the particle beam 204 producing a minimal beam throat 206 at a distance of about 1.75 mm from the end of the convergent nozzle tip 202.

The particle beam 204 is comprised of a carrier fluid, which is typically, but not exclusively nitrogen. The particle beam 204 is further geometrically shaped by the action of a sheath fluid 208, also typically, but not exclusively nitrogen. Characteristics of both the sheath and carrier fluids are that they tend not to be chemically reactive with either the particles in the particle beam 204, or the intended substrate target.

To further improve the tip design to produce less overspray and thinner deposited lines, two main characteristics of the aerosol particulate flow must be improved: beam width, and beam collimation.

The first potential improvement is the beam width, which has a direct relationship with the deposited line width. The beam width can be minimized by improving the focus of the beam. If focusing is used, there will be a single stand-off distance at which the smallest line widths may be obtained, but only if the aerosol particles are monodisperse, that is, having very nearly the same particle size. Otherwise focusing will be greatly reduced, and line widths will inversely be increased.

The second potential improvement is the collimation of the beam. Beam collimation reduces overspray, and decreases the dependence of the deposited line width on the tip-to-substrate or stand-off distance. Overspray is reduced because aerosol particles are now moving together in a straight line.

When the tip is designed to focus the aerosol particles, aerosol particles of different size will focus at different focal points. Focusing is most effective with monodisperse particles, but it is generally difficult to achieve perfectly monodisperse particles.

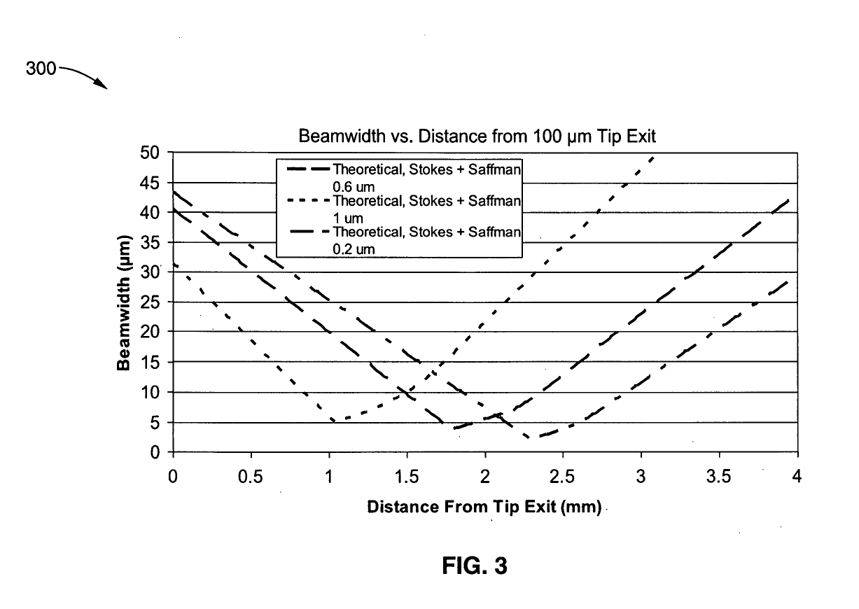

Refer now to FIG. 3, which models the effect of particle size on focusing distance. Here, theoretical models of particles using both the Saffman and Stokes forces are modeled for particle sizes of: 0.2, 0.6, and 1.0 μm. Notice that if a beam were to have all three particle sizes that the beam width would be much wider than each individual particle size. Also, the range of distance that the particles are focused is much less, with a maximum focusing occurring at approximately 1.7 mm from the tip exit.

Near perfect collimation can be achieved with a long capillary of constant diameter. This can be used for collimating the aerosol particles, but clogging of the long capillary would likely result. To reduce clogging, the length that the tip geometry at its smallest diameter needs to be reduced, thereby reducing the length having a higher probability of clogging. The length where the tip has its smallest diameter may be minimized by arranging three nozzles in series. The particles will then become much more collimated, and in certain theoretical cases may become completely collimated.

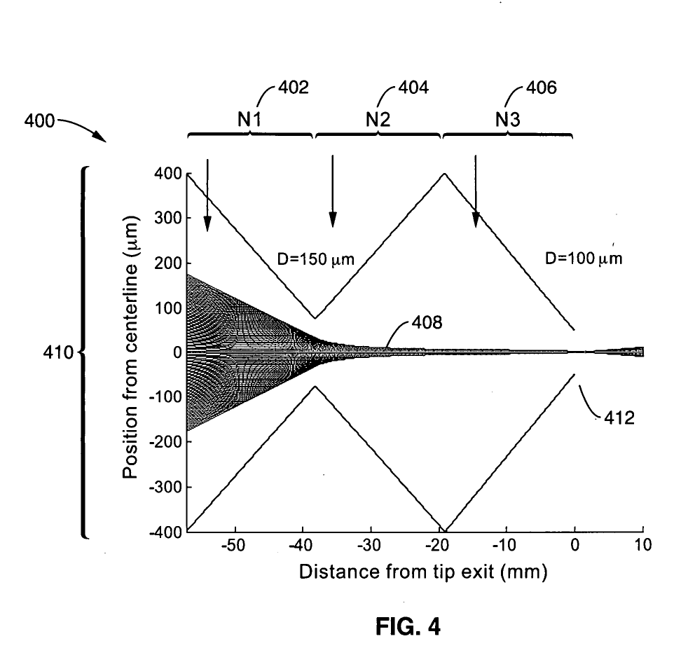

Refer now to FIG. 4, which shows the geometry of a Convergent-Divergent-Convergent (CDC) system comprising 3 nozzle stages in series 400. Here, there is a first nozzle 402 (N1), a second nozzle 404 (N2), and a third nozzle 406 (N3). Notice that by the time the particle beam 408 reaches the third nozzle 406 (N3) it is already focused to about 6% of the total diameter 410 (800 μm diameter, at the entrance the first nozzle 402 (N1). The third nozzle 406 (N3) does not appear to focus the particles, but mainly serves to accelerate the particle beam 408. The third nozzle 406 (N3) may not be necessary if the nozzle is spraying into a substantially low vacuum (e.g. 100 milliTorr or less) ambient pressure. If the particles that comprise the particle beam 408 were not accelerated with the third nozzle 406 (N3), they would exit at a velocity on the order of 1 m/s. With such a low velocity, the particles would be subject to airflows outside the two nozzle system (the third nozzle 406 (N3) missing in this instance), and possibly deflected prior to reaching an intended substrate at the proper location. With high velocities (on the order of 100 m/s) the particles will eject out of the tip exit 412 of the third nozzle 406 (N3) with their trajectories likely being much less affected by the ambient atmospheric pressure or bulk fluid movement.

Although not detailed here, the three nozzles may be constructed monolithically, or may be separately constructed and joined together to form the CDC nozzle. Alternatively, the nozzles may be constructed of shaped ceramic, and joined together with a plastic coupling.

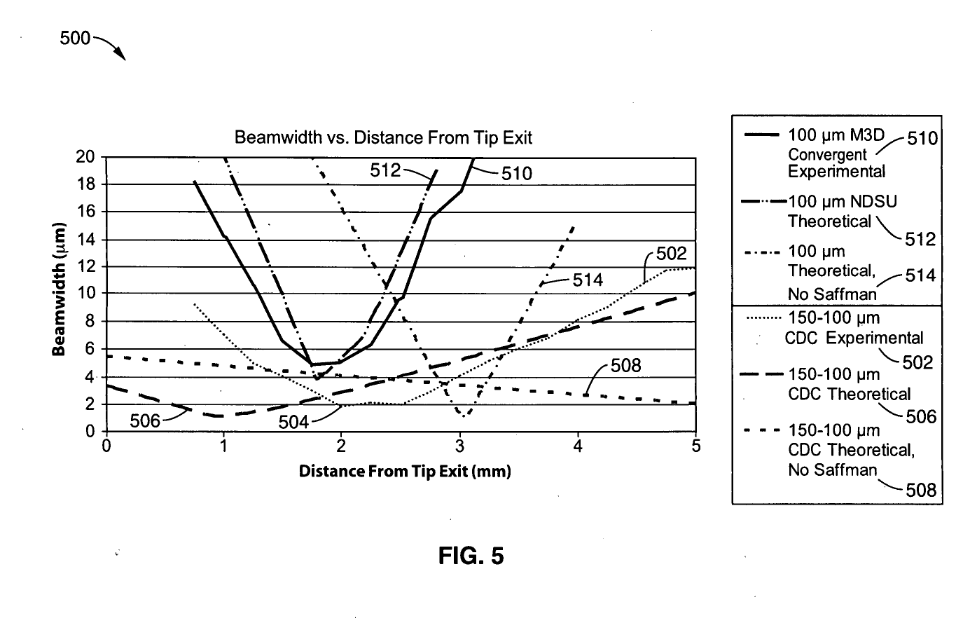

Refer now to FIG. 5, which is an experimental and analytical analysis graph 500 of the performance of the Convergent-Divergent-Convergent (CDC) nozzle 400 of FIG. 4.

The particle flow beam width leaving the new nozzle design 400 of FIG. 4 was also analyzed and compared to the old nozzle tip 202 design of FIG. 2. It appears in FIG. 5 that the beam width of the new CDC nozzle 400 of FIG. 4 is thinner and more collimated than the old nozzle tip 202 design of FIG. 2.

Still referring to FIG. 5, the beam width remains small even to 5 mm past the tip where it has a width of only 12 μm. A CDC nozzle with a 150 μm diameter at the second nozzle 404 minimum diameter (or throat) of FIG. 4, and 100 μm diameter at the third nozzle 406 throat is referred to as a 150-100 μm nozzle. With the 150-100 μm nozzle, the beam width appears 504 to be about 1.9 μm at about 2 mm past the tip exit.

When the 150-100 μm nozzle experimental results 502 are compared to the theoretical curves for both Saffman forces and Stokes forces 506, and Stokes only forces 508, it can be seen that again the curve for Saffman +Stokes forces 506 most closely matches the experimental curve 502, however the variance r² value is only 0.44.

Similarly, the convergent single nozzle 202 results of FIG. 2 were previously shown in FIG. 3, and have been rescaled to fit the scales of FIG. 5 to allow for a comparison between the performances of both the convergent single nozzle 202 and the CDC nozzle 400 of FIG. 4. On FIG. 5, these rescaled plots are shown as the 100 μm Convergent Experimental 510 plot, the 100 μm Saffman + Stokes Theoretical 512 plot, and the 100 μm Stokes-only Theoretical 514 plot. As these various plots have already been described previously regarding FIG. 3, they will not be reconsidered here.

One possible reason for the deviation between the experimental 502 curve and theoretical values with the Saffman force 506 is because the 3-nozzle tip is only a prototype. The fluid connection between each of the three nozzles may not be perfect, and the centerlines of the nozzles may not be in perfect alignment. Additionally, the diameters may not be axisymmetric. Improvements in tip geometry and construction would likely improve the correlation between the theoretical 506 and experimental 502 results. Additionally, the theoretical model could be re-analyzed to determine if the rate of change of the nozzle diameter might affect the assumed Poiseuillian profile.

The collimation of the beam width should be advantageous for depositions in which the vertical thickness of the deposition at a specific distance across the width changes significantly. To test the performance of the CDC nozzle 400 of FIG. 4 compared to the single-nozzle convergent tip 202 of FIG. 2 over a varying stand-off distance, an experiment was devised where a line was to be written over a 1 mm step moving from a standoff distance of 2 mm to 3 mm or vice versa.

Refer now to FIG. 6, which is a perspective view of the geometry of the 1 mm step writing experiment 600. The initial stand-off height from the CDC nozzle 602 to the substrate 604 was 2 mm 606, and when the CDC nozzle 602 tip passed the 1 mm vertical 608 step 610, the stand-off distance increased to 3 mm.

From the experimental results shown for the single nozzle 510 and CDC nozzle 502 of FIG. 5, it should be apparent that the beam width greatly increases for the single-nozzle design, while beam width remains nearly constant for the CDC design. The increase in beam width should result in an increased line width as a fixed beam passes over a substrate with increasing surface distance. In this instance, as the initial nozzle to substrate distance increases from 2 mm to 3 mm, increases in line width should result.

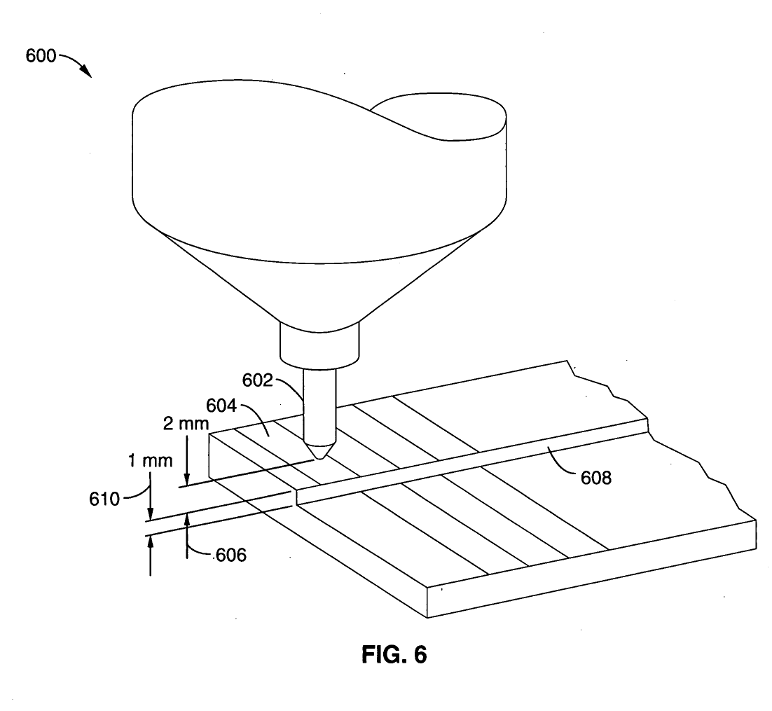

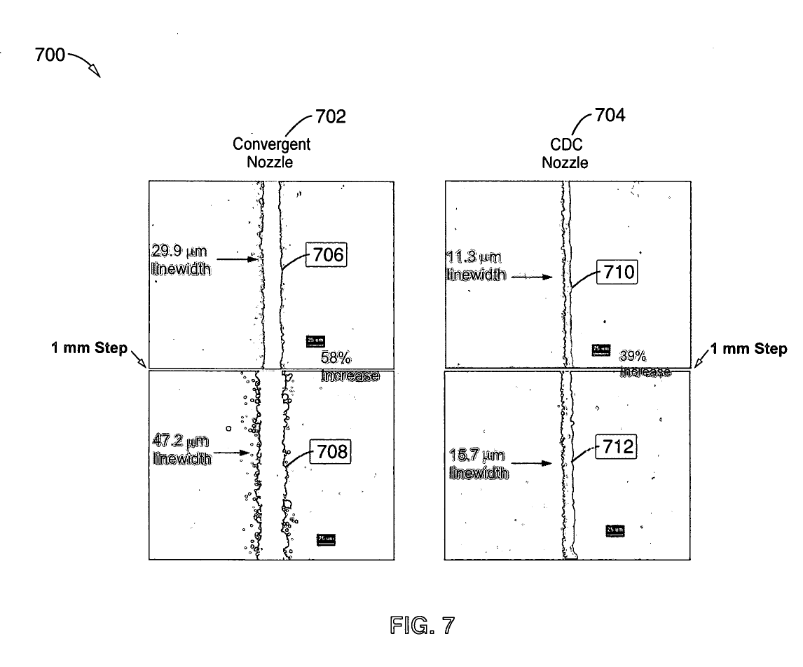

Refer now to FIG. 7, where the results of the deposited lines from the test geometry of FIG. 6 may be seen 700. Both the convergent nozzle 702 and the CDC nozzle 704 used a 100 μm diameter as the final nozzle orifices, and the CDC design used a 150 μm diameter for convergent constriction between the first and second nozzles. These nozzles correspond to those previously discussed as the convergent nozzle 202 of FIG. 2, and the CDC nozzle 400 of FIG. 4.

Harima ink product code NPS-J (from Harima Chemicals, 4-4-7 Imabashi, Chuo-ku, Osaka 541-0042 Japan), with 50 nm silver particle size (57-62 wt. %) in n-tetradecane solvent (27-34 wt. %) and proprietary dispersant molecules (8-12 wt. %) was used with 25 SCCM of carrier fluid, sheath fluid flow of 15 SCCM, and a substrate stage velocity of 30 mm/s. The resulting precursor lines were measured both before (unsintered) and after subsequent processing. Both the carrier fluid and the sheath fluid were dry nitrogen.

The convergent nozzle 702 created precursor lines 29.9 μm wide 706 at a stand-off distance of 2 mm. When the stand-off distance was increased to 3 mm, line width 708 increased to 47.2 μm, a 58% increase in line width.

The CDC nozzle 704 produced precursor lines 11.3 μm wide 710 at a stand-off distance of 2 mm, and 15.7 μm wide lines 712 at a stand-off distance of 3 mm. The CDC nozzle 704 design had a line width increase of only 39% despite a 1 mm jump in CDC nozzle to substrate distance.

The results after subsequent processing of the precursor Harima ink are even more promising: the convergent nozzle 702 had line widths of 23.8 μm and 42.8 μm for a stand-off distance of 2 mm and 3 mm respectively. The convergent nozzle line width therefore increased by 80%. The CDC nozzle 704, by comparison, achieved line widths of 10.7 μm and 13.6 μm for stand-off distances of 2 mm and 3 mm respectively. The CDC nozzle 704 achieved a line width increase of only 27%.

Experimental results of the deposited line width comparison experiment of FIG. 7 confirm that the CDC nozzle is indeed more collimated and has a thinner resulting line width than the single convergent nozzle. The lines produced by the CDC nozzle 704 were approximately 60% thinner than those produced by the convergent nozzle 702. Also, the change in line width over the 1 mm step detailed in FIG. 6 was up to 53% less for the 3-nozzle tip vs. the single-nozzle tip. Additional improvements to the design of the CDC nozzle could be accomplished once the aerosol particle size distribution, particle density, and particle velocity field exiting the tip are characterized. Also, the ability to design CDC nozzles with varying geometry would be greatly beneficial.

### EXAMPLE 2

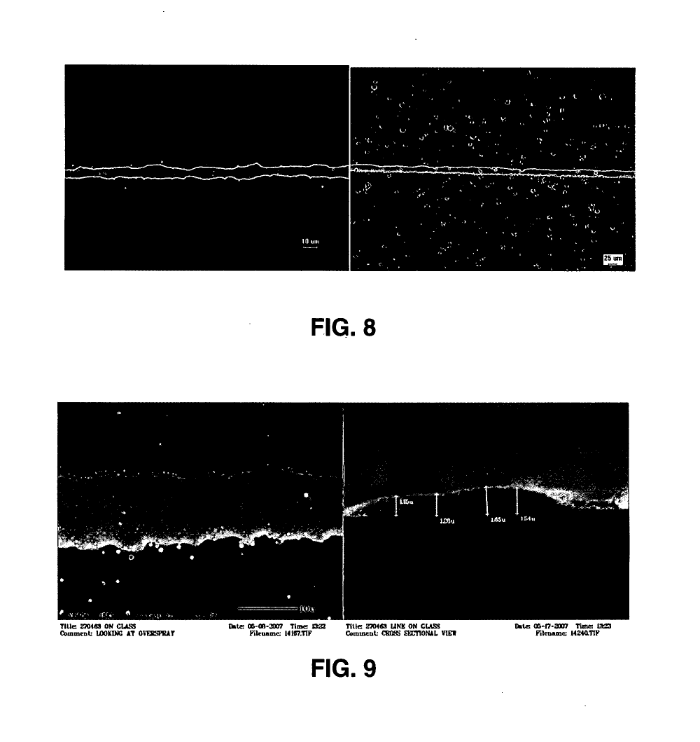

Refer now to FIGS. 8-12, which show the results of steps taken to improve line widths and qualities.

Refer now to FIG. 8. Improved deposited line-widths were achieved by using the CDC nozzle design with modified gas flow rates, which resulted in lines as thin as 8 μm in the left frame. The lines were created with 15 SCCM carrier fluid, 25 SCCM sheath fluid, a substrate translational speed of 10 mm/s, using Nano-Size silver nano-particle ink. The conductor precursor ink used was produced by Nano-Size LTD. (Migdal Ha'Emek, Israel) is a solid-in-liquid dispersion with 30-50 wt. % silver particles (with 50 nm diameters) in a solvent mixture of water and ethylene glycol with up to 3 wt. % dispersants. An example of a line produced by the new nozzle can be seen in FIG. 8. The edge definition in this case is not optimized given the irregular wetting of the ink with the surface as shown in the left frame of FIG. 8. Lines of 25 μm can also be created where the overspray is markedly reduced as seen in the right frame of FIG. 8.

Refer now to FIG. 9, where increased magnification SEM images visualize the lines shown in FIG. 8. The left frame shows a small degree of overspray and a degree of irregular border to the line. The right frame shows a cross section of the line, which reveals that the line is between about 1 μm and 1.65 μm in thickness, and about 11 μm wide. The measured locations on the cross section are about 1.15, 1.28, 1.65, and 1.54 μm thick respectively, left to right. Note that these lines in the SEM pictures were drawn on glass and have not been subsequently processed.

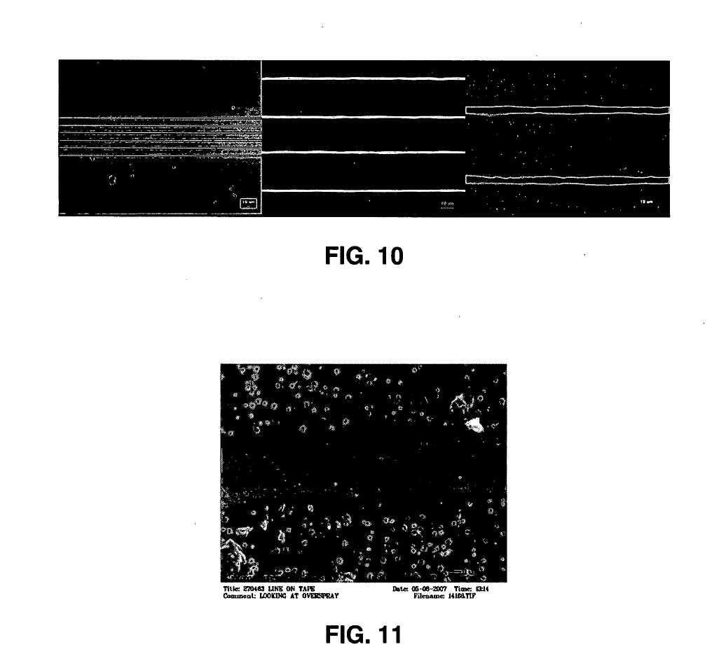

Refer now to FIG. 10, where the lines shown in the SEM micrographs above were also written on double-sided tape (e.g., soft polymer or polymer/polyimide material). It was noted that the lines were visibly smaller than lines written on glass. Optical photomicrographs can be seen in the left frame FIG. 10, and increase in magnification from the left to right frames. It was determined that the line widths of the lines in view were approximately 3.7 μm.

Refer now to FIG. 11, which is a SEM image of one of the lines of FIG. 10. In the SEM image, the line width appears slightly larger than those shown in FIG. 10, with a width of approximately 5.3 μm. Notice that the edge is also more difficult to distinguish due to substantial overspray.

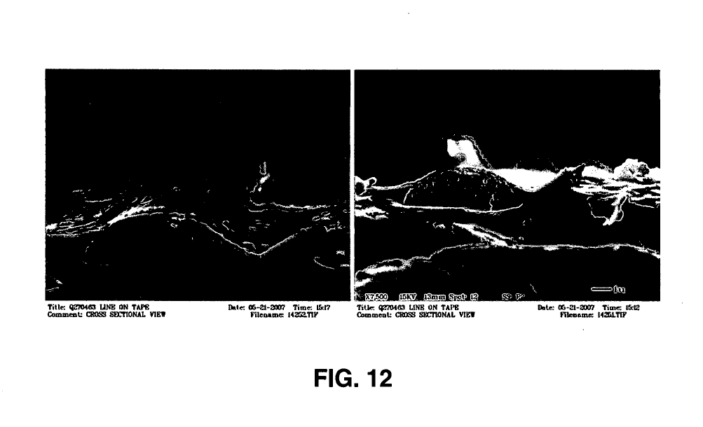

Refer now to FIG. 12, which is a SEM image of a line (previously shown in FIG. 10) on double-sided tape that has been cross-sectioned. It was noticed that the line formed a trough as it deposited on the substrate. Apparently, the trough is formed through some form of particle-substrate interaction. The trough is approximately 1 μm deep and extends horizontally underneath the trough increasing the line-width to approximately 6.2 μm. The trough has the function of decreasing line-width, improving edge definition, and increasing the line aspect ratio (line height/line width).

The concept of simultaneously creating a trough while printing a line is novel, and can produce thinner lines, with a shape closer to (although still far from) a cylindrical shape.

Experimental research continues to improve these troughing techniques. It is hoped that such techniques, while useful in and of themselves, might also prove extremely beneficial to high frequency resonance structures. It is known that spattering of the line material outside the confines of the intended line causes eddy current losses, reducing Q, and reducing performance of such structures.

These structures might be simply inductive lines, but may be formed in multiple layers as both capacitors and inductors.

### CONCLUSION

In further examples, lines were successfully written on doped- and undoped-silicon, as well as on glass, polyimide, and polymers, which demonstrates that the invention is not limited to any particular print media.

It will also be appreciated that, while a tip having 3 nozzles in series represents a one aspect of the invention, any configuration using at least 3 series nozzles is also within the scope of the present invention. In another aspect of the invention, the number of nozzles is a higher order odd number (i.e. an odd number of nozzles greater than one).

Additionally, the tip can be formed from juxtaposed separate nozzles or as a single monolithic structure.

It is further contemplated that, with the tip described herein, an aerosol of liquid or liquid particle suspension generated and mixed with a sheath gas would be input into the tip and patterned on a target.

All patents, publications and other references cited herein are incorporated herein by reference in their entirety.

Although the description above contains many details, these should not be construed as limiting the scope of the invention but as merely providing illustrations of some of the presently preferred embodiments of this invention. Therefore, it will be appreciated that the scope of the present invention fully encompasses other embodiments which may become obvious to those skilled in the art, and that the scope of the present invention is accordingly to be limited by nothing other than the appended claims, in which reference to an element in the singular is not intended to mean “one and only one” unless explicitly so stated, but rather “one or more.” All structural, chemical, and functional equivalents to the elements of the above-described preferred embodiment that are known to those of ordinary skill in the art are expressly incorporated herein by reference and are intended to be encompassed by the present claims. Moreover, it is not necessary for a device or method to address each and every problem sought to be solved by the present invention, for it to be encompassed by the present claims. Furthermore, no element, component, or method step in the present disclosure is intended to be dedicated to the public regardless of whether the element, component, or method step is explicitly recited in the claims. No claim element herein is to be construed under the provisions of 35 U.S.C. 112, sixth paragraph, unless the element is expressly recited using the phrase “means for.”

What is claimed is:

1. An aerosolized particle deposition apparatus, comprising:
(a) a final output port; and
(b) means for spraying particles through the final output port.

2. The apparatus of claim 1, wherein the means for spraying particles through the final output port comprises:
(a) a first nozzle having an input port, an output port, and a length, said first nozzle having a taper along its length, said output port of said first nozzle having a diameter smaller than its input port;
(b) a second nozzle in series with said first nozzle, said second nozzle having an input port, an output port, and a length, said input port contiguous with said output port of said first nozzle, said second nozzle having a taper along its length, said output port of said second nozzle having a diameter larger than its input port; and
(c) a third nozzle in series with said second nozzle, said third nozzle having an input port, said final output port, and a length, said input port contiguous with said output port of said second nozzle, said third nozzle having a taper along its length, said final output port of said third nozzle having a diameter smaller than its input port.

3. The apparatus of claim 2, wherein the diameter of the input port of the first nozzle is approximately 800 μm.

4. The apparatus of claim 2, wherein the diameter of the output port of the first nozzle is approximately 50 μm to approximately 200 μm.

5. The apparatus of claim 2, wherein the diameter of the input port of the second nozzle is approximately 50 μm to approximately 200 μm.

6. The apparatus of claim 2, wherein the diameter of the output port of the second nozzle is approximately 800 μm.

7. The apparatus of claim 2, wherein the diameter of the input port of the third nozzle is approximately 800 μm.

8. The apparatus of claim 2, wherein the diameter of the final output port of the third nozzle is approximately 50 μm to approximately 200 μm.

9. The apparatus of claim 2, wherein each nozzle has a length of approximately 9 mm to approximately 20 mm.

10. The apparatus of claim 2, wherein:
(a) the diameter of the input port of the first nozzle is approximately 800 μm,
(b) the diameter of the output port of the first nozzle is approximately 150 μm,
(c) the diameter of the input port of the second nozzle is approximately 150 μm,
(d) the diameter of the output port of the second nozzle is approximately 800 μm,
(e) the diameter of the input port of the third nozzle is approximately 800 μm, and
(f) the diameter of the final output port of the third nozzle is approximately 100 μm.

11. The apparatus of claim 2, wherein:
(a) the diameter of the input port of the first nozzle is approximately 800 μm;
(b) the diameter of the output port of the first nozzle is approximately 150 μm;
(c) the diameter of the input port of the second nozzle is approximately 200 μm;
(d) the diameter of the output port of the second nozzle is approximately 800 μm;
(e) the diameter of the input port of the third nozzle is approximately 800 μm; and
(f) the diameter of the final output port of the third nozzle is approximately 100 μm.

12. The apparatus of claim 2, wherein each of the three nozzles has a length of approximately 20 mm.

13. The apparatus of claim 2, wherein each of the three nozzles wherein each respective taper is selected from a group of tapers consisting of: substantially linear within about 1%, substantially linear within about 5%, substantially linear within 10%, substantially linear within 50%, and substantially linear within greater than 50%.

14. The apparatus of claim 2, wherein the two nozzles in series extend from and are coaxial with the nozzle further from the final output.

15. An aerosolized particle deposition apparatus, comprising:
(a) a first nozzle having an input port, an output port, and a length, said first nozzle having a taper along its length, said output port of said first nozzle having a diameter smaller than its input port;
(b) a second nozzle extending from and coaxial with said first nozzle, said second nozzle having an input port, an output port, and a length, said input port contiguous with said output port of said first nozzle, said second nozzle having a taper along its length, said output port of said second nozzle having a diameter larger than its input port; and
(c) a third nozzle extending from and coaxial with said second nozzle, said third nozzle having an input port, an output port, and a length, said input port contiguous with said output port of said second nozzle, said third nozzle having a taper along its length, said output port of said third nozzle having a having a diameter smaller than its input port.

16. An apparatus as recited in claim 15, wherein the diameter of the input port of the first nozzle is approximately 800 μm.

17. An apparatus as recited in claim 15, wherein the diameter of the output port of the first nozzle is approximately 50 μm to approximately 200 μm.

18. An apparatus as recited in claim 15, wherein the diameter of the input port of the second nozzle is approximately 50 μm to approximately 200 μm.

19. An apparatus as recited in claim 15, wherein the diameter of the output port of the second nozzle is approximately 800 μm.

20. An apparatus as recited in claim 15, wherein the diameter of the input port of the third nozzle is approximately 800 μm.

21. An apparatus as recited in claim 15, wherein the diameter of the output port of the third nozzle is approximately 50 μm to approximately 200 μm.

22. An apparatus as recited in claim 15, wherein each nozzle has a length of approximately 9 mm to approximately 20 mm.

23. An apparatus as recited in claim 15, wherein the diameter of the input port of the first nozzle is approximately 800 μm, the diameter of the output port of the first nozzle is approximately 150 μm, the diameter of the input port of the second nozzle is approximately 150 μm, the diameter of the output port of the second nozzle is approximately 800 μm, the diameter of the input port of the third nozzle is approximately 800 μm, and the diameter of the output port of the third nozzle is approximately 100 μm.

24. An apparatus as recited in claim 15, wherein the diameter of the input port of the first nozzle is approximately 800 μm, the diameter of the output port of the first nozzle is approximately 150 μm, the diameter of the input port of the second nozzle is approximately 200 μm, the diameter of the output port of the second nozzle is approximately 800 μm, the diameter of the input port of the third nozzle is approximately 800 μm, and the diameter of the output port of the third nozzle is approximately 100 μm.

25. An apparatus as recited in claim 15, wherein each nozzle has a length of approximately 20 mm.

26. An aerosolized particle deposition apparatus, comprising the nozzles of claim 15.

27. A method of aerosol particle deposition, comprising:
(a) providing a stream of aerosolized particles in a carrier fluid;
(b) providing a sheath fluid;
(c) flowing the aerosolized particle stream within the sheath fluid to form a combined flow; and
(d) flowing the combined flow through a series of convergent, then divergent, then convergent (CDC) nozzles.

28. The method of claim 27, comprising:
(a) flowing the combined flow past a last output port in the CDC nozzle; and
(b) impacting a substrate with the combined flow,
(c) whereby aerosolized particles are deposited onto the substrate.

29. The method of claim 27, wherein the aerosolized particles comprise nanostructures with minimum dimensions selected from a group of minimum dimensions consisting of: less than 1 nm, less than 10 nm, less than 100 nm, less than 1 μm, and greater than or equal to 1 μm.

30. The method of claim 27, wherein the aerosolized particle stream comprises precursor inks that contain conductive particles.

31. The method of claim 30, wherein the conductive particles are nanostructures.

32. The method of claim 30, wherein the precursor inks comprise conducting precursor inks that yield electronic-grade materials selected from a group of conductive materials consisting of: Al, Au, Ag, Cu, Ni and C.

33. The method of claim 30, wherein the precursor inks comprise semiconducting precursor inks that yield electronic-grade materials selected from a group of materials consisting of: Si, Ge, GaAs, GaInAs, AlGaAs, InP, ZnO, SnO₂, In₂O₃, CdO, Ga₂O₃ as semiconductors and other materials that transform from a precursor to an electronic material.

34. A product produced by the process of claim 27.

35. A conductive trace produced on a substrate by the process of claim 27.

36. A semiconductor device produced on a substrate by the process of claim 27.

37. The method of claim 27, wherein the sheath fluid is substantially chemically inert relative to the aerosolized particles.

38. The method of claim 27, wherein the carrier fluid is substantially chemically inert relative to the aerosolized particles.

39. The method of claim 27, wherein the carrier fluid and sheath fluid are substantially nitrogen N₂.

40. The method of claim 27, wherein the carrier fluid and sheath fluid are substantially dry air.
